(19) United States
(12) Patent Application Publication
(10) Pub. No.: US 2026/0013165 A1
(43) Pub. Date: Jan. 8, 2026

(54) GATE OXIDE THICKNESS CONTROL

(71) Applicant: Taiwan Semiconductor Manufacturing Company, Ltd., Hsinchu (TW)

(72) Inventors: Chang-Ta Chen, New Taipei City (TW); Ming-Chang Wen, Kaohsiung City (TW); Kuo-Feng Yu, Hsinchu County (TW); Chia-Cheng Chen, Hsin-Chu City (TW); Sih-Jie Liu, Hsinchu County (TW); Chu-Yen Hsiao, Taoyuan City (TW); Shi-Sheng Hu, Tainan City (TW); Tsai-Yu Huang, Taoyuan (TW); Keng-Yao Chen, Hsinchu (TW); Yun Lee, Taipei City (TW)

(21) Appl. No.: 18/765,082

(22) Filed: Jul. 5, 2024

(51) Int. Cl. H01L 29/66; H01L 21/02; H01L 21/3115; H01L 21/324

(52) U.S. Cl. CPC H10D 30/014; H01L 21/02362; H01L 21/31155; H01L 21/324; H10D 64/017; H10D 64/018

(57) ABSTRACT

A method according to the present disclosure includes receiving a structure that includes a source/drain feature sandwiched between a first channel region and a second channel region, a first dummy gate stack over the first channel region, a first gate spacer extending along a sidewall of the first dummy gate stack, a second dummy gate stack over the second channel region, a second gate spacer extending along a sidewall of the second dummy gate stack, and an interlayer dielectric (ILD) layer over the source/drain feature and disposed between the first gate spacer and the second gate spacer, selectively recessing the ILD layer to form a top recess, after the selectively recessing, performing an ion implantation process to the structure, and after the ion implantation process, forming a capping layer in the top recess.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of method 100 for forming a semiconductor device, according to one or more aspects of the present disclosure.

FIGS. 2-18 illustrate fragmentary cross-sectional views of a work-in-progress (WIP) structure during a fabrication process according to the method of FIG. 1, according to one or more aspects of the present disclosure.

FIG. 19 illustrates a flowchart of method 300 for forming a semiconductor device, according to one or more aspects of the present disclosure.

FIGS. 20-38 illustrate fragmentary cross-sectional views of a work-in-progress (WIP) structure during a fabrication process according to the method of FIG. 19, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Throughout the present disclosure, source/drain region(s) may refer to a source or a drain, individually or collectively dependent upon the context.

The present disclosure is generally related to GAA transistors and fabrication methods thereof. GAA transistors may be fabricated using a replacement gate process, where a dummy gate stack is formed as a placeholder and is subsequently replaced with a functional gate structure. The sidewalls of the dummy gate stack are covered with a gate spacer, which helps define the boundary of the dummy gate stack. After formation of source/drain feature, the dummy gate stack is removed and replaced with a functional gate structure. The functional gate structure may include an interfacial layer that is formed using an oxidation process. It has been observed that dangling bonds present on surfaces of the gate spacer may lead to increase of the thickness of the interfacial layer. A thicker interfacial layer may lead to increase of channel resistance or reduction of channel current. It can be seen that the presence of dangling bonds on the gate spacer may be a source of process variation.

The present disclosure provides methods for forming a GAA transistor. In an example process, a fin-shaped structure with channel layers and sacrificial layers is formed over a substrate. After formation of a dummy gate stack over a channel region of the fin-shaped structure, at least one gate spacer is formed over the dummy gate stack, source/drain regions of the fin-shaped structure are recessed. After source/drain features are formed over the source/drain regions, a contact etch stop layer (CESL) and an interlayer dielectric (ILD) layer are deposited over the source/drain feature. The ILD layer is then selectively recessed to form a top recess. An ion implantation process and an anneal process are then performed to neutralize surface dangling bonds on the at least one gate spacer. After the anneal process, a capping layer is formed over the top recess. The dummy gate stack is then removed and channel layers in channel regions are released. A gate structure is formed to wrap around each of the channel layers. The ion implantation process and the anneal process not only may prevent thickening of the interfacial layer in the gate structure but may strain the channel layers for improved performance.

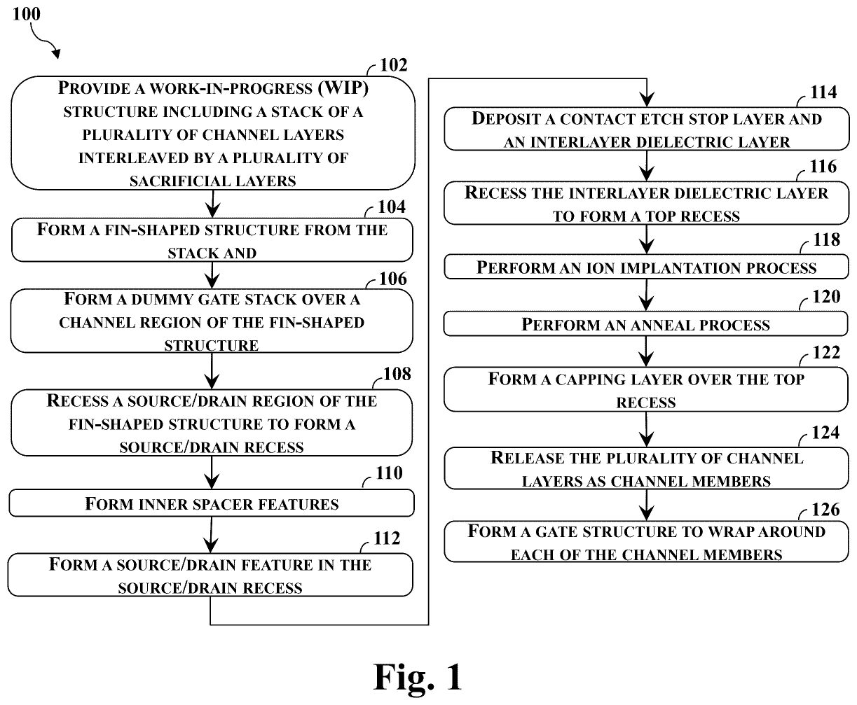

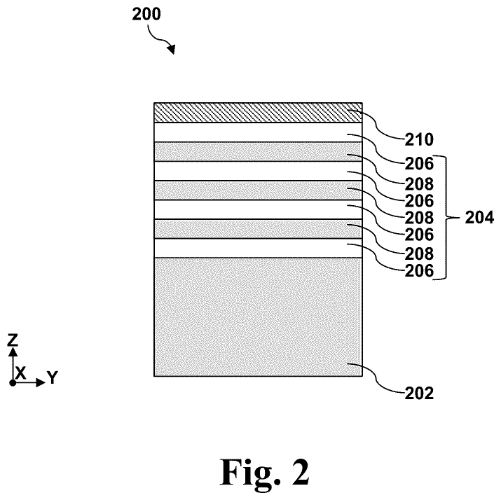

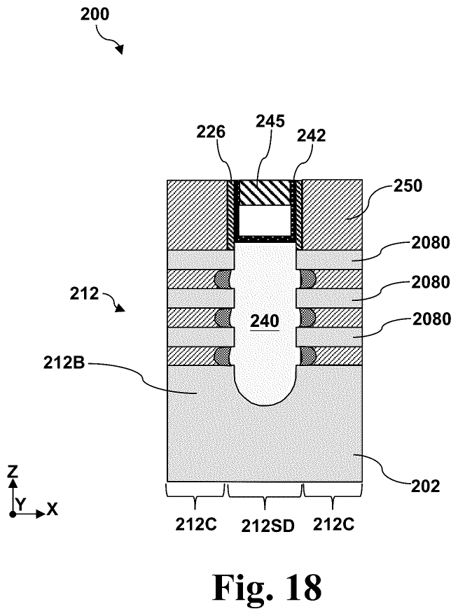

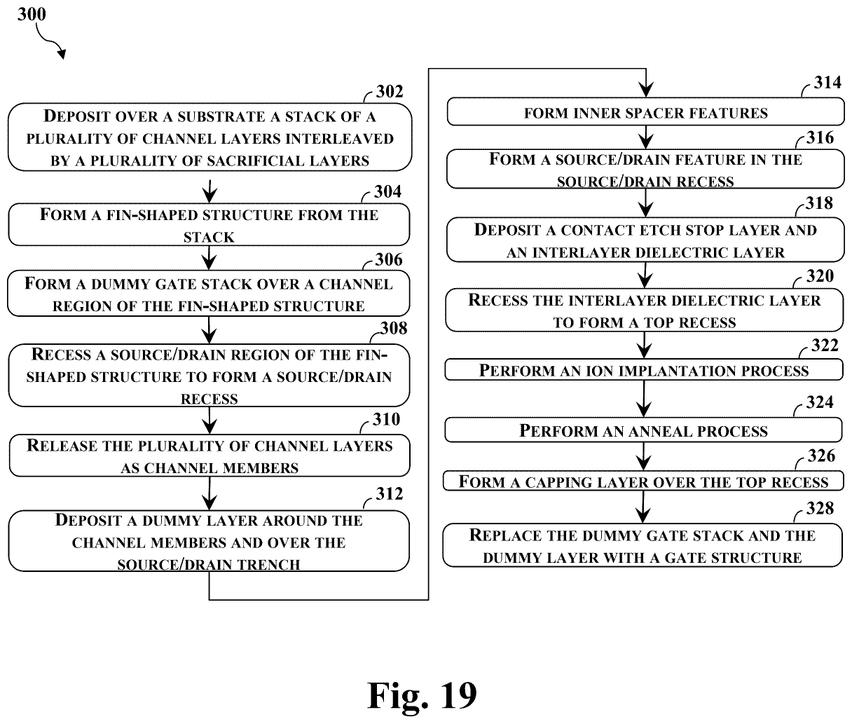

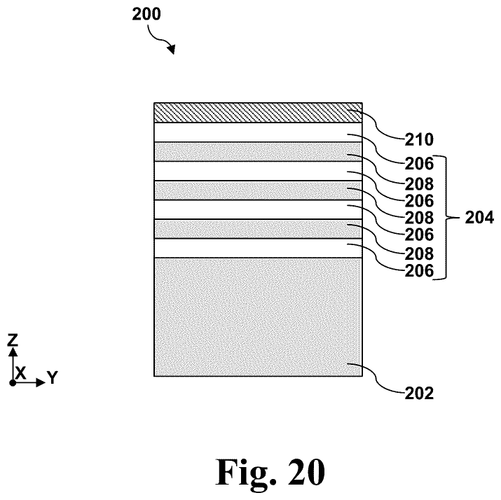

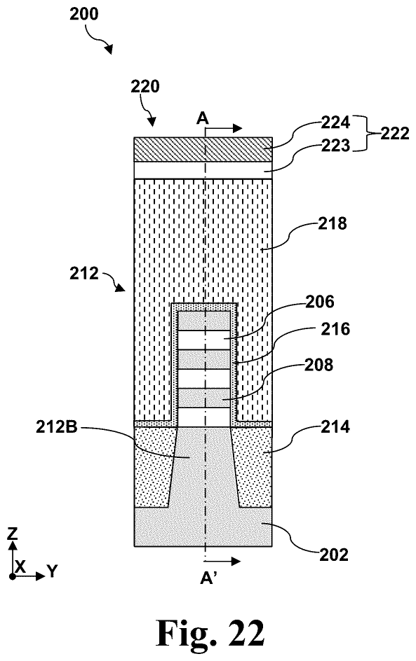

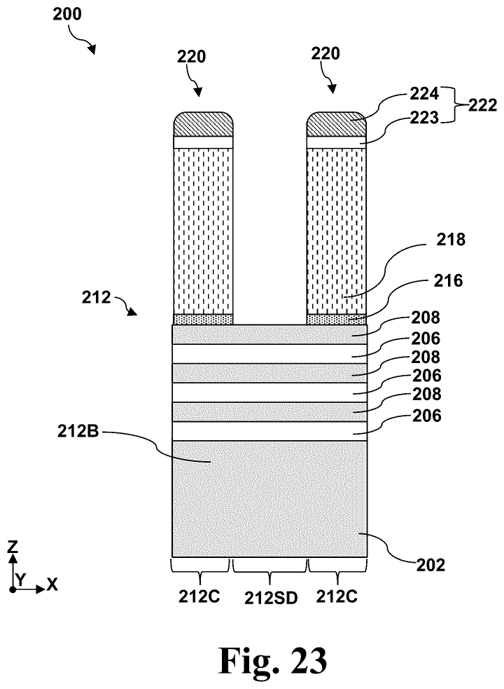

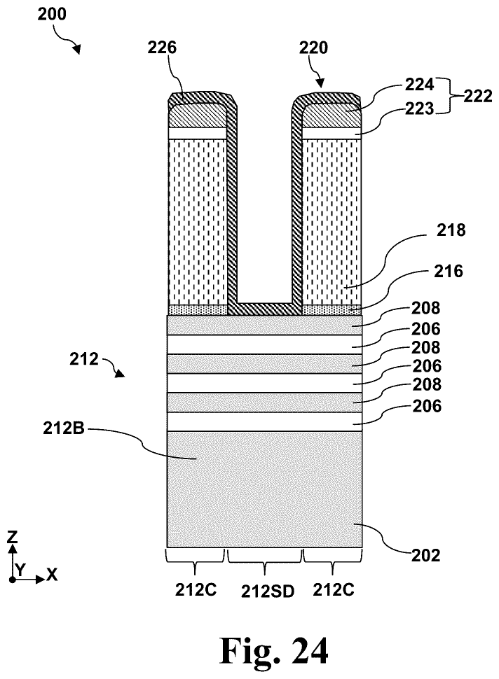

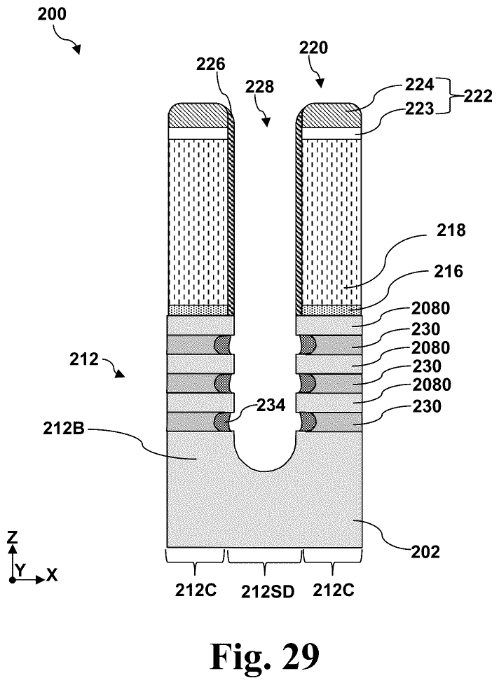

The various aspects of the present disclosure will now be described in more detail with reference to the figures. In that regard, FIG. 1 and FIG. 18 are flowcharts illustrating method 100 and method 300 of forming a semiconductor structure from a work-in-progress (WIP) structure according to embodiments of the present disclosure. Method 100 and 300 are merely examples and are not intended to limit the present disclosure to what is explicitly illustrated in method 100 and method 300. Additional steps can be provided before, during and after method 100 or method 300, and some steps described can be replaced, eliminated, or moved around for additional embodiments of the method. Not all steps are described herein in detail for reasons of simplicity. Method 100 is described below in conjunction with FIG. 2-18, which are fragmentary cross-sectional views of a WIP structure 200 at different stages of fabrication according to embodiments of the method 100 in FIG. 1. Method 300 is described below in conjunction with FIG. 20-38, which are fragmentary cross-sectional views of a WIP structure 200 at different stages of fabrication according to embodiments of the method 300 in FIG. 19. Because the WIP structure 200 will be fabricated into a semiconductor structure or a semiconductor device, the WIP structure 200 may be referred to herein as a semiconductor structure 200 or a semiconductor device 200 as the context requires. For avoidance of doubts, the X, Y and Z directions in FIGS. 2-18 and 20-38 are perpendicular to one another. Throughout the present disclosure, unless expressly described otherwise, like reference numerals denote like features or steps.

Method 100 and method 300 are both methods of forming GAA transistors. Both method 100 and method 300 start out by forming a stack over a substrate, where the stack includes a plurality of channel layers interleaved by a plurality of sacrificial layers. Both method 100 and method 300 include steps to pattern the stack to form fin-shaped structures. Method 100 keeps the sacrificial layers in channel regions of the fin-shaped structures until after formation of source/drain features in source/drain regions of the fin-shaped structures. Different from method 100, method 300 removes the sacrificial layers after formation of dummy gate stacks and deposits a dummy layer to interleave the channel layers. The dummy layer is removed after formation of source/drain features in the source/drain regions of the fin-shaped structures. Method 100 and method 300 will be described below. Detailed descriptions of similar operations may be omitted for brevity. Like references referred to in conjunction with descriptions of method 100 and method 300 should be deemed interchangeable unless otherwise expressly described in the present disclosure. Attention is first directed to method 100 in FIG. 1.

Referring to FIGS. 1 and 2, method 100 includes a block 102 where a stack 204 of alternating semiconductor layers is formed over the WIP structure 200. As shown in FIG. 2, the WIP structure 200 includes a substrate 202. In some embodiments, the substrate 202 may be a semiconductor substrate such as a silicon (Si) substrate. The substrate 202 may include various doping configurations depending on design requirements. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor compositions may be different. In some embodiments, the sacrificial layers 206 include silicon germanium (SiGe) or germanium tin (GeSn) and the channel layers 208 include silicon (Si). It is noted that four (4) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

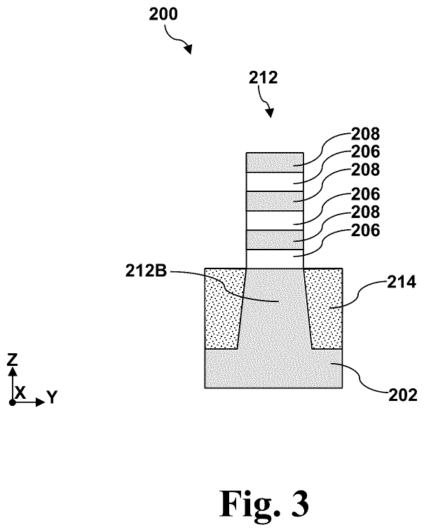

Referring to FIGS. 1 and 3, method 100 includes a block 104 where a fin-shaped structure 212 is formed from the stack 204 and the substrate 202. To pattern the stack 204, a hard mask layer 210 (shown in FIG. 2) may be deposited over the stack 204 to form an etch mask. The hard mask layer 210 may be a single layer or a multi-layer. For example, the hard mask layer 210 may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202. The patterned stack 204, including the sacrificial layers 206 and the channel layers 208, is disposed directly over the base fin structure 212B.

At block 104, an isolation feature 214 is formed adjacent to the fin-shaped structure 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is embedded or buried in the isolation feature 214.

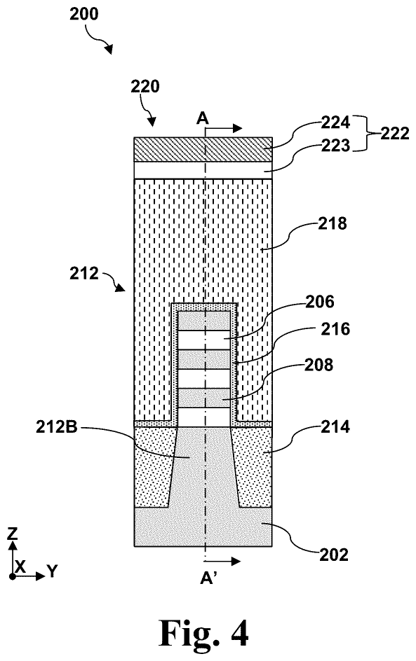

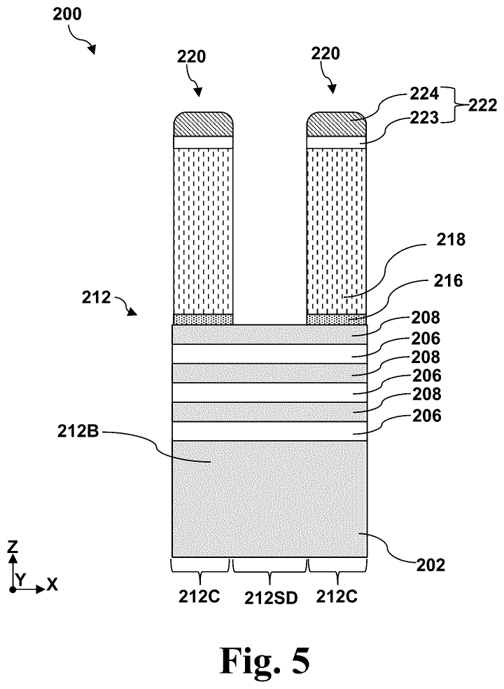

Referring to FIGS. 1, 4 and 5, method 100 includes a block 106 where a dummy gate stack 220 is formed over a channel region 212C of the fin-shaped structure 212. In some embodiments, a gate replacement process (or gate-last process) is adopted where the dummy gate stack 220 (shown in FIGS. 4 and 5) serves as a placeholder to undergo various processes and is to be removed and replaced by a functional gate structure. Other processes and configuration are possible. In some embodiments illustrated in FIG. 5, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the WIP structure 200. In some embodiments, the dummy dielectric layer 216 may be formed on the fin-shaped structure 212 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, the dummy gate stack 220 is patterned such that it is only disposed over the channel region 212C, not disposed over the source/drain region 212SD.

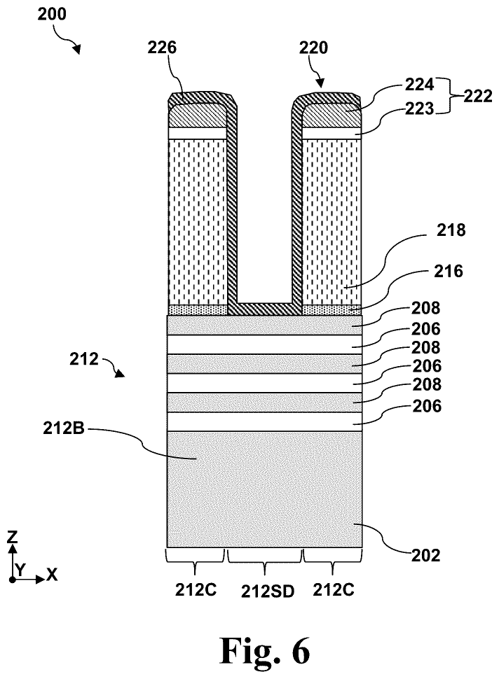

Referring to FIGS. 1 and 6, at block 106, a gate spacer layer 226 is deposited over the WIP structure 200, including over the dummy gate stack 220. In some embodiments, the gate spacer layer 226 is deposited conformally over the WIP structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

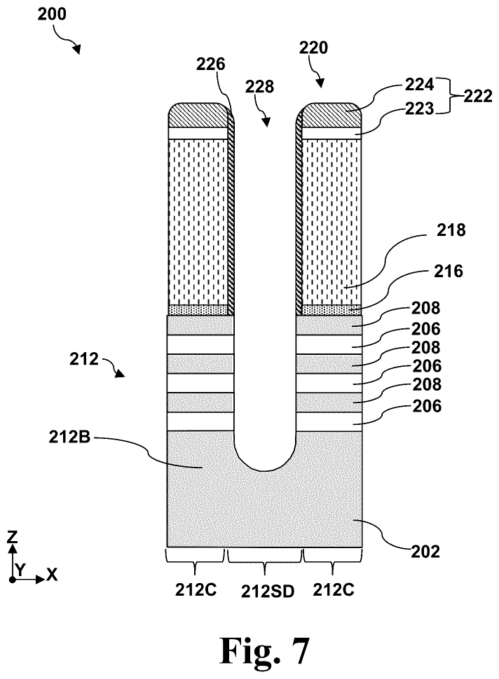

Referring to FIGS. 1 and 7, method 100 includes a block 108 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202 below the source/drain regions 212SD. The resulting source/drain trench 228 extends vertically through the depth of the stack 204 and partially into the substrate 202. An example dry etch process for block 108 may implement an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 7, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

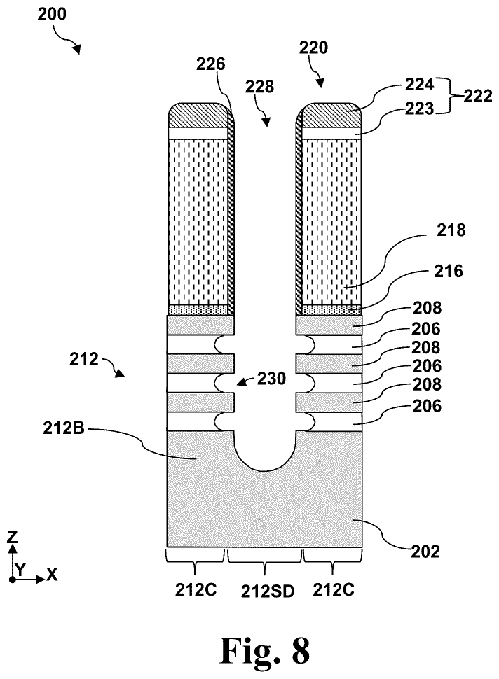

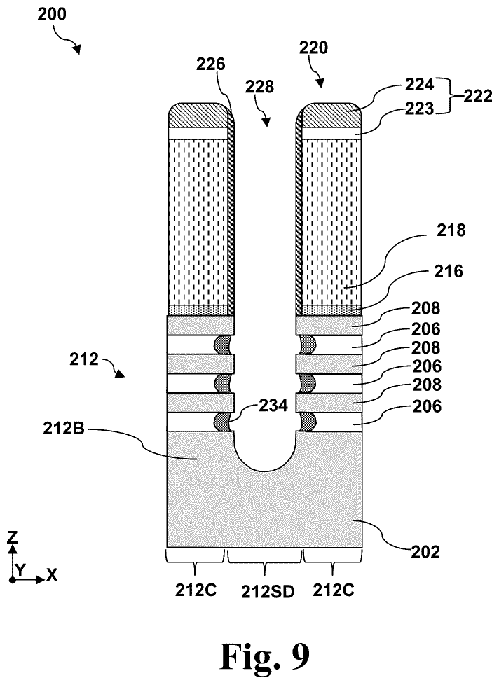

Referring to FIGS. 1, 8 and 9, method 100 includes a block 110 where inner spacer features 234 are formed. While not shown explicitly, operation at block 112 may include selective and partial removal of the sacrificial layers 206 to form inner spacer recesses 230 (shown in FIG. 8), deposition of inner spacer material over the WIP structure 200, and etch back the inner spacer material to form inner spacer features 234 in the inner spacer recesses 230 (shown in FIG. 9). Referring to FIG. 8, the sacrificial layers 206 exposed in the source/drain trenches 228 are selectively and partially recessed to form inner spacer recesses 230 while the gate spacer layer 226, the exposed portion of the substrate 202, and the channel layers 208 are substantially unetched. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

After the inner spacer recesses 230 are formed, an inner spacer material is deposited over the WIP structure 200, including over the inner spacer recesses 230. The inner spacer material may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses 230 as well as over the sidewalls of the channel layers 208 exposed in the source/drain trenches 228. Referring to FIG. 9, the deposited inner spacer material is then etched back to remove the inner spacer material from the sidewalls of the channel layers 208 to form the inner spacer features 234 in the inner spacer recesses 230. At block 110, the inner spacer material may also be removed from the top surfaces and/or sidewalls of the gate-top hard mask layer 222 and the gate spacer layer 226. As shown in FIG. 9, each of the inner spacer features 234 is in direct contact with the recessed sacrificial layers 206 and is disposed vertically (along the Z direction) between two neighboring channel layers 208.

While not explicitly shown, before any of the epitaxial layers are formed, method 100 may include a cleaning process to clean surfaces of the WIP structure 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

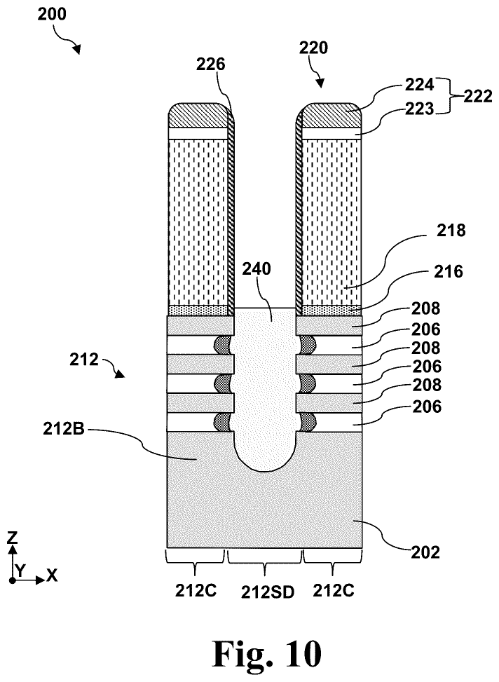

Referring to FIGS. 1 and 10, method 100 includes a block 112 where a source/drain feature 240 is formed over the source/drain region 212D. The source/drain feature 240 may be n-type or p-type. When the source/drain feature 240 is n-type, it may include silicon (Si) and an n-type dopant, such as phosphorus (P), arsenic (As), antimony (Sb), or a combination thereof. When the source/drain feature 240 is p-type, it may include silicon germanium (SiGe) and a p-type dopant, such as boron (B) or boron difluoride (BF₂). In some embodiments, the source/drain feature 240 may include multiple epitaxial layers with different dopant concentrations. In some implementations, the source/drain feature 240 may be deposited using a molecular beam epitaxy (MBE) process, a vapor phase deposition (VPE) process, and/or other suitable epitaxial growth processes.

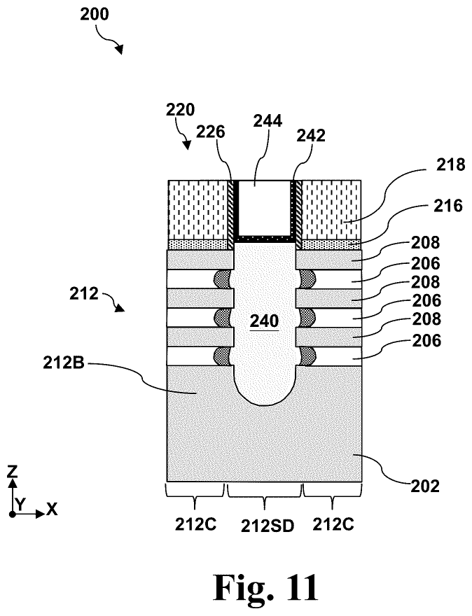

Referring to FIGS. 1 and 11, method 100 includes a block 114 where a contact etch stop layer (CESL) 242 and an interlayer dielectric (ILD) layer 244 are deposited. Referring to FIG. 11, the CESL 242 is deposited over the WIP structure 200, including over the source/drain feature 240. The CESL 242 may include silicon nitride or aluminum nitride. In some implementations, the CESL 242 may be deposited using CVD or ALD. The ILD layer 244 is then deposited over the CESL 242. In some embodiments, the ILD layer 244 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be deposited using CVD, FCVD, spin-on coating, or a suitable deposition technique. After the deposition of the ILD layer 244, the WIP structure 200 may be planarized by a planarization process to expose the dummy gate stack 220.

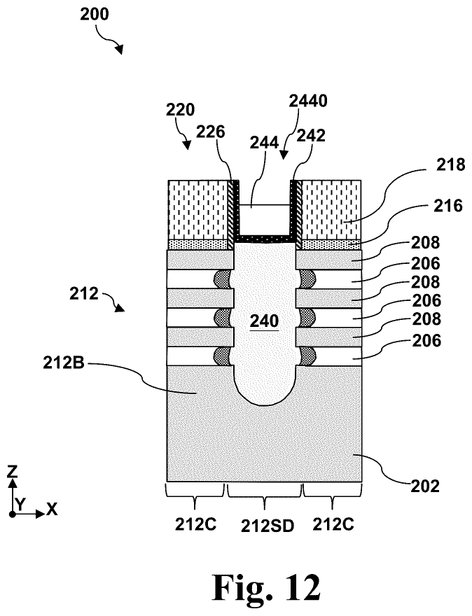

Referring to FIGS. 1 and 12, method 100 includes a block 116 where the ILD layer 244 is recessed to form a top recess 2440. In order to protect the ILD layer 244 from being damaged during the channel release steps, the ILD layer 244 is anisotropically and selectively recessed to form a top recess 2440. In some embodiments, the anisotropic etch of the ILD layer 244 may include use of plasma of a fluorine-containing gas (e.g., CF₄, SF₆, CH₂F₂, CHF₃, C₂F₆, and/or C₃F₆).

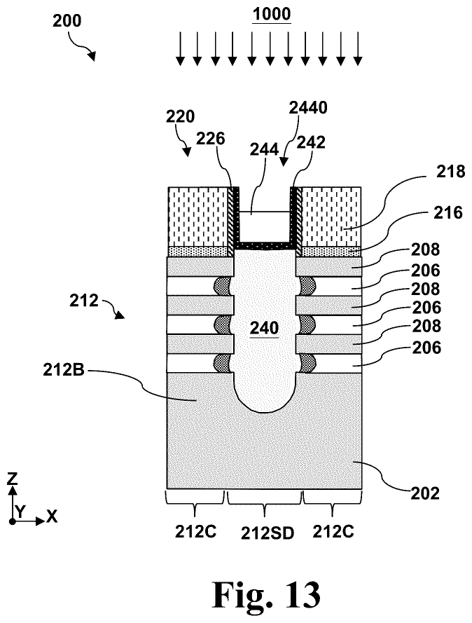

Referring to FIGS. 1 and 13, method 100 includes a block 118 where an ion implantation process 1000 is performed. In some embodiments, the ion implantation process 1000 implants nitrogen (N₂), germanium (Ge), or silicon (Si). In one embodiment, the ion implantation process 1000 implants nitrogen (N₂). In some implementations, the ion implantation process 1000 includes an ion implantation energy between about 0.5 keV and about 2 keV. This implantation energy range is not trivial because it represents the implantation range required for the implantation to reach the CESL 242 without inflicting damages on the source/drain features 240. In terms of dosage, the ion implantation process 1000 may include a dosage between about 5×10¹⁴ cm⁻² and about 2×10¹⁵ cm⁻². Because the ion implantation process 1000 is performed after the ILD layer 244 is recessed and before a capping layer is formed over the top recess 2440, the ion implantation process 1000 can better reach dangling bonds on the gate spacer 226. The ion implantation process 1000 is configured to neutralize the dangling bonds on or around the gate spacer 226 without causing undesirable irreversible damages to neighboring structures.

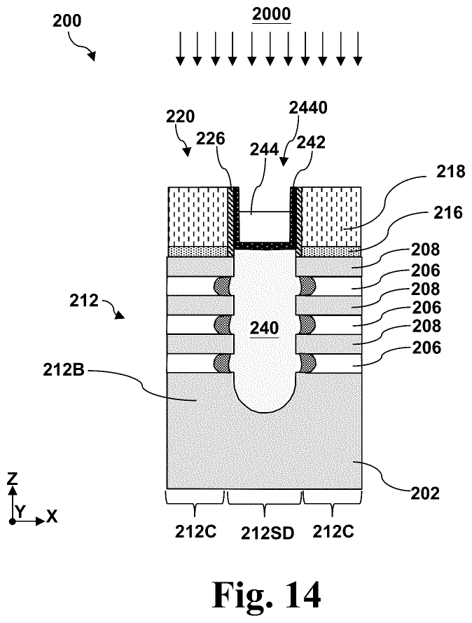

Referring to FIGS. 1 and 14, method 100 includes a block 120 where an anneal process 2000 is performed. While parameters of the ion implantation process 1000 are selected to minimize damages, it inevitably may cause damaged bonds near or around the gate spacer 226. These damaged bonds, if left untreated, may become source of dangling bonds or oxygen atoms. At block 120, the anneal process 2000 is performed to repair and reduce damages or defects caused by the ion implantation process 1000. In some embodiments, the anneal process 2000 may include a micro sub-second anneal (μssA). In some instances, the anneal process 2000 may include an anneal temperature between about 900° C. and about 1300° C. and an anneal time between about 100 milliseconds and about 10 seconds.

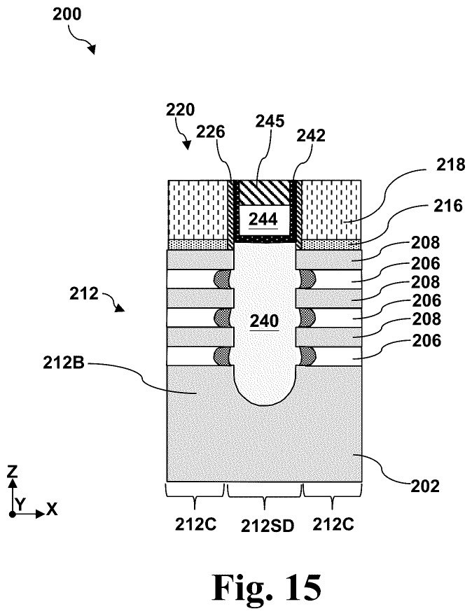

Referring to FIGS. 1 and 15, method 100 includes a block 122 where a capping layer 245 is formed over the top recess 2440. In some embodiments, the capping layer 245 may include a dielectric material that allows selective etching of dummy gate electrode 218, the dummy gate dielectric layer 216, and the sacrificial layers 206. In some embodiments, the capping layer 245 may include silicon nitride. The capping layer 245 functions to protect the ILD layer 244 from being damaged during the removal of sacrificial layers 206. A planarization process is performed to remove excess capping layer 245 and to expose the dummy gate stack 220. After the planarization, top surfaces of the capping layer 245, the CESL 242, the gate spacer layer 226, and the dummy gate stacks 220 are coplanar.

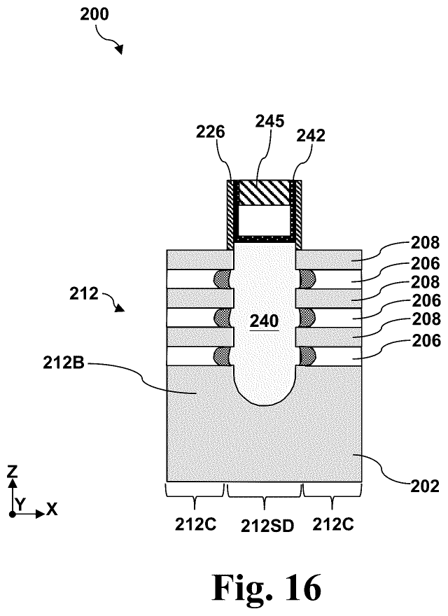

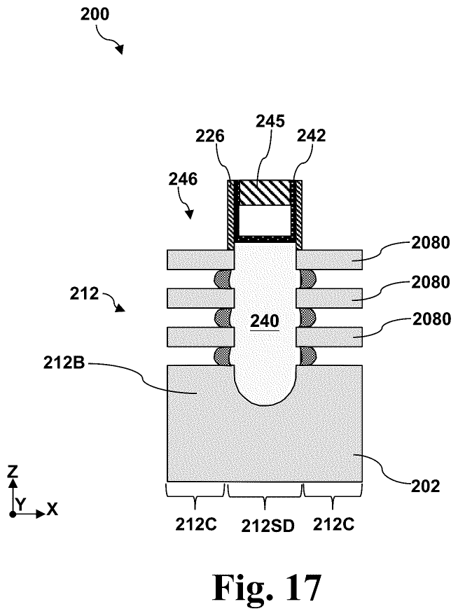

Referring to FIGS. 1, 16 and 17, method 100 includes a block 124 where the plurality of channel layers 208 are released as channel members 2080. Operations at block 124 may include removal of the dummy gate stack 220 (shown in FIG. 16) and selective removal of the sacrificial layers 206 to release the channel layers 208 (shown in FIG. 17. Reference is first made to FIG. 16. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed. The sacrificial layers 206 between the channel layers 208 in the channel region 212C are selectively removed. The selective removal of the sacrificial layers 206 releases the channel layers 208 to form channel members 2080 shown in FIG. 17. The selective removal of the sacrificial layers 206 forms a gate trench 246 that includes spaces between adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

Referring to FIGS. 1 and 18, method 100 includes a block 126 where a gate structure 250 is formed to wrap around each of released as channel members 2080. After the release of the channel members 2080, the gate structure 250 is formed to wrap around each of the channel members 2080. While not explicitly shown, the gate structure 250 includes an interfacial layer interfacing the channel members 2080 and the substrate 202 in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation or thermal oxidation. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 250 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure includes portions that interpose between channel members 2080 in the channel region 212C.

The performance of the ion implantation process 1000 at block 118 and the anneal process 2000 at block 120 reduces population of dangling bonds along sidewalls of the gate spacer 226. When the interfacial layer is formed at block 126 using chemical oxidation or thermal oxidation, a thickness of the interfacial layer is smaller. Experimental data show that performance of the ion implantation process 1000 may reduce the effective gate oxide thickness, increase on-state current, and reduce channel resistance. Additionally, experimental data also indicate that when the ion implantation process 1000 is not performed, the ILD layer 244 exhibits a compressive stress. However, when the ion implantation process 1000 is performed, the ILD layer 244 exhibits a tensile stress that may help increase carrier mobility, especially for p-type GAA transistors.

Attention is now turned to method 300 in FIG. 19.

Referring to FIGS. 19 and 20, method 300 includes a block 302 where a stack 204 of alternating semiconductor layers is formed over the WIP structure 200. Operations at block 302 are substantially similar to those at block 102 described above. Accordingly, detailed description of the operations at block 302 are omitted for brevity.

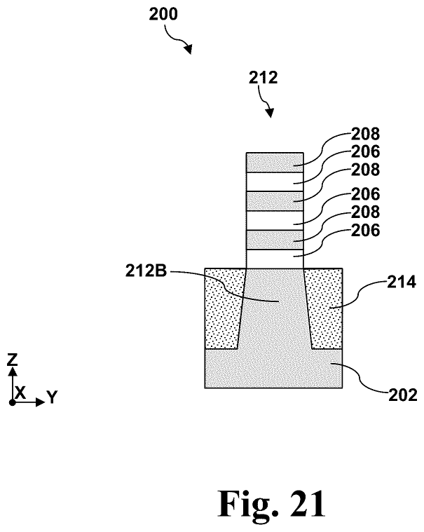

Referring to FIGS. 19 and 21, method 300 includes a block 304 where a fin-shaped structure 212 is formed from the stack 204 and the substrate 202. Operations at block 304 are substantially similar to those at block 104 described above. Accordingly, detailed description of the operations at block 304 are omitted for brevity.

Referring to FIGS. 19 and 22-24, method 300 includes a block 306 where a dummy gate stack 220 is formed over a channel region 212C of the fin-shaped structure 212. Operations at block 306 are substantially similar to those at block 106 described above. Accordingly, detailed description of the operations at block 306 are omitted for brevity.

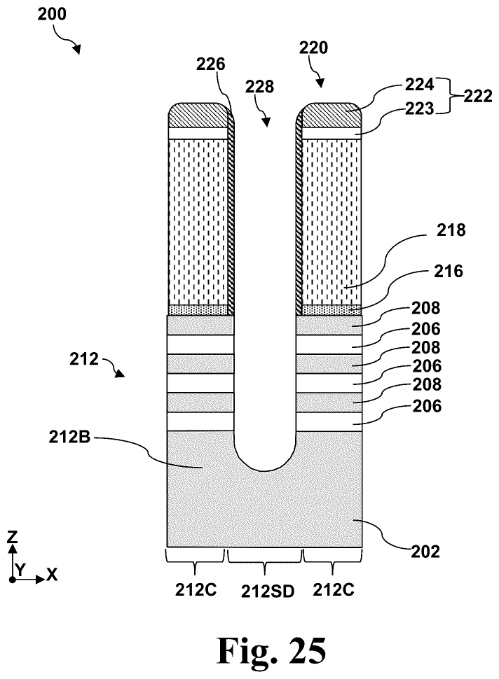

Referring to FIGS. 19 and 25, method 300 includes a block 308 where a source/drain region 212SD of the fin-shaped structure 212 is anisotropically recessed to form a source/drain trench 228. Operations at block 308 may be substantially similar to those at block 108 described above. Accordingly, detailed description of the operations at block 308 are omitted for brevity.

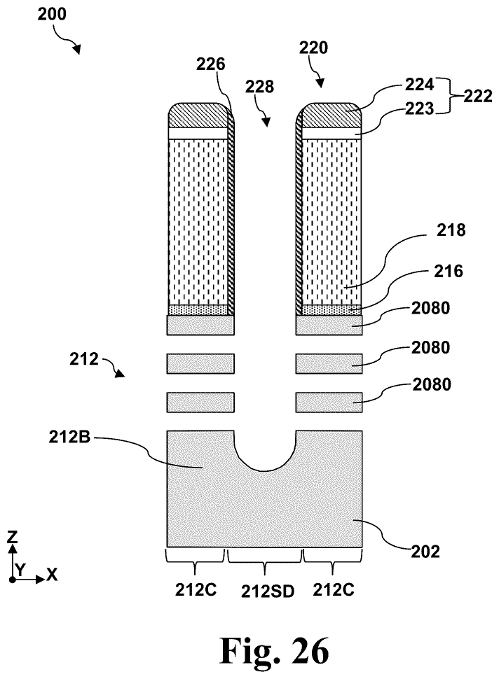

Referring to FIGS. 19 and 26, method 300 includes a block 310 where the plurality of channel layers 208 in the channel regions are released as channel members 2080. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 25) to form channel members 2080 shown in FIG. 26. The selective removal of the sacrificial layers 206 forms spaces between and around adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

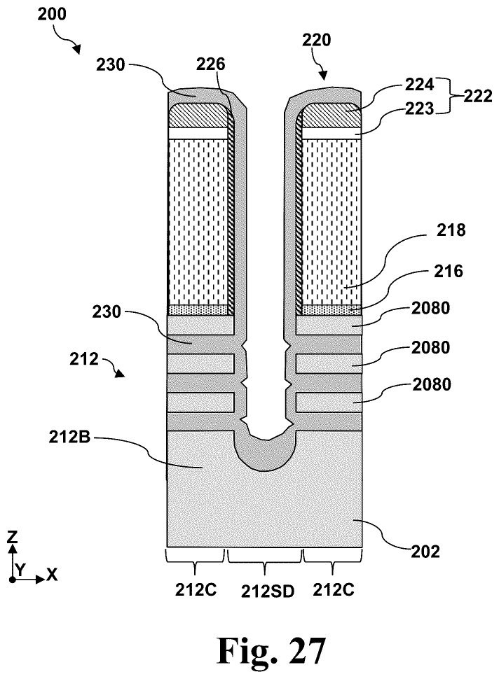

Referring to FIGS. 19 and 27, method 300 includes a block 312 where a dummy layer 230 is deposited around the channel members 2080 and over the source/drain trenches 228. The dummy layer 230 may include silicon oxide and may be deposited using plasma enhanced chemical vapor deposition (PECVD) or ALD. As shown in FIG. 27, the dummy layer 230 fills the spaces among the channel members 2080 and covers end sidewalls of the channel members 2080. Additionally, the dummy layer 230 is in direct contact with a sidewall of the gate spacer layer 226 and a top surface of the substrate 202. Depending on the design, the channel members 2080 may take form of nanowires, nanosheets, or other nanostructures.

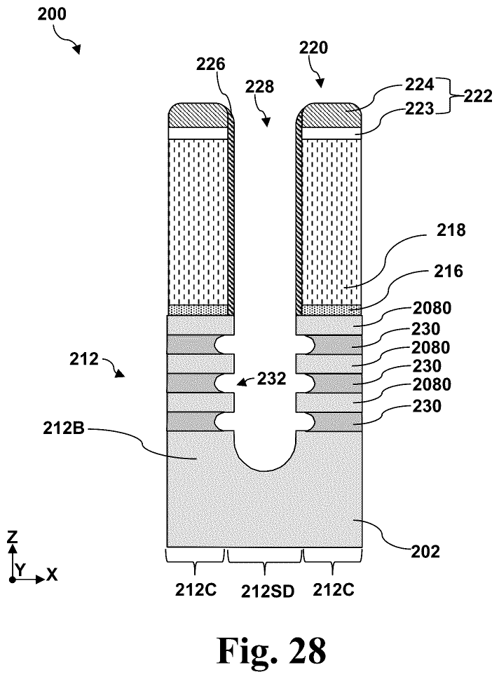

Referring to FIGS. 19, 28 and 29, method 300 includes a block 314 where inner spacer features 234 are formed. Referring to FIG. 28, the dummy layers 230 are selectively and partially recessed to form inner spacer recesses 232 while the gate spacer layer 226, the dummy gate stack 220, the exposed portion of the substrate 202, and the channel layers 208 are substantially unetched. In an embodiment where the channel layers 208 consist essentially of silicon (Si) and the dummy layers 230 are formed of silicon oxide, the selective recess of the dummy layer 230 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

To form the inner spacer features, an inner spacer layer is deposited over WIP structure 200, including over the source/drain trench 228 and the inner spacer recesses 232. In some embodiments, the inner spacer layer may include silicon carbonitride (SiCN), silicon oxycarbonitride (SiOCN), silicon nitride (SiN), silicon oxycarbide (SiOC), or silicon oxynitride (SiON). In some implementations, the inner spacer layer may be deposited using CVD or ALD. The deposited inner spacer layer is then etched back to form inner spacer features 234 in the inner spacer recesses 232. In some embodiments, the etching back may include use of a dry etch process, such as a reactive ion etching (RIE) process that is aided by plasma. An example dry etch process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof.

While not explicitly shown, before any of the epitaxial layers are formed, method 300 may include a cleaning process to clean surfaces of the WIP structure 200, especially surfaces of the channel members 2080 and the substrate 202. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

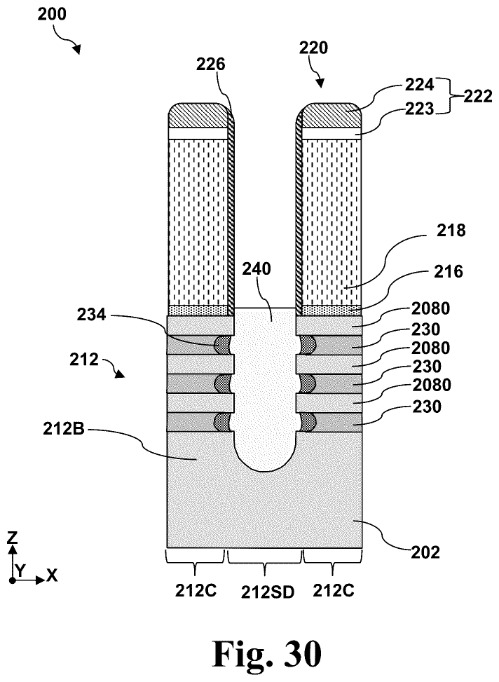

Referring to FIGS. 19 and 30, method 300 includes a block 316 where a source/drain feature 240 is formed over the source/drain region 212SD. While not explicitly shown in the figures, the source/drain feature 240 may include a bottom epitaxial feature and a main epitaxial feature over the bottom epitaxial feature. The source/drain feature 240 may be n-type or p-type. When the source/drain feature 240 is n-type, the bottom epitaxial feature may include undoped silicon (Si) or undoped silicon germanium (SiGe) and the main epitaxial feature may include silicon (Si) and an n-type dopant, such as phosphorus (P), arsenic (As), antimony (Sb), or a combination thereof. When the source/drain feature 240 is p-type, the bottom epitaxial feature may include undoped silicon (Si) or undoped silicon germanium (SiGe) and the main epitaxial feature may include silicon germanium (SiGe) and a p-type dopant, such as boron (B), boron difluoride (BF₂), or a combination thereof. As used herein, the undoped semiconductor material is regarded as undoped when it is not intentionally doped. In some alternative embodiments, the bottom epitaxial feature may include a counter dopant to reduce leakage into the bulk substrate 202. For example, the bottom epitaxial feature in an n-type source/drain feature 240 may include a p-type dopant, such as boron (B). For another example, the bottom epitaxial feature in a p-type source/drain feature 240 may include an n-type dopant, such as phosphorus (P), arsenic (As), or antimony (Sb). The source/drain feature 240 may be formed using vapor-phase epitaxy (VPE), ultra-high vacuum CVD (UHV-CVD), or molecular beam epitaxy (MBE). Doping of the source/drain features 240 may be achieved with in-situ doping.

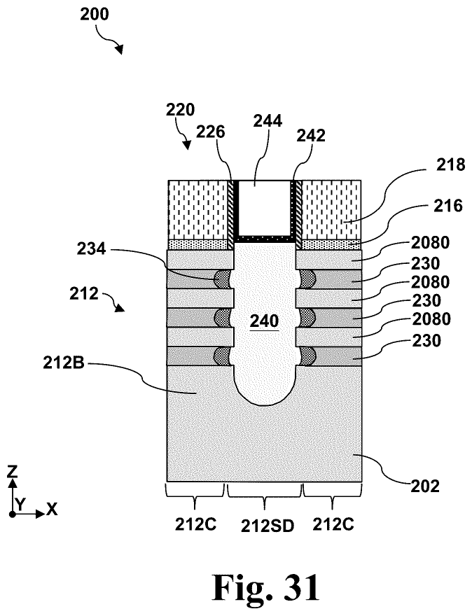

Referring to FIGS. 19 and 31, method 100 includes a block 318 where a contact etch stop layer (CESL) 242 and an interlayer dielectric (ILD) layer 244 are deposited. At block 318, the CESL 242 is deposited over the WIP structure 200, including over the source/drain feature 240. The CESL 242 may include silicon nitride or aluminum nitride. In some implementations, the CESL 242 may be deposited using CVD or ALD. The ILD layer 244 is then deposited over the CESL 242. In some embodiments, the ILD layer 244 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be deposited using CVD, FCVD, spin-on coating, or a suitable deposition technique. After the deposition of the ILD layer 244, the WIP structure 200 may be planarized by a planarization process to expose the dummy gate stack 220. After the planarization process, top surfaces of the dummy gate stack 220, the CESL 242, the ILD layer 244, and the gate spacer 226.

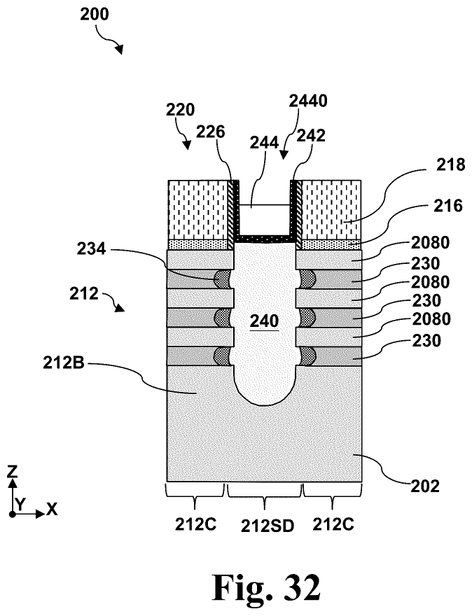

Referring to FIGS. 19 and 32, method 300 includes a block 320 where the ILD layer 244 is recessed to form a top recess 2440. In order to protect the ILD layer 244 from being damaged during the channel release steps, the ILD layer 244 is anisotropically and selectively recessed to form a top recess 2440. In some embodiments, the anisotropic etch of the ILD layer 244 may include use of plasma of a fluorine-containing gas (e.g., CF₄, SF₆, CH₂F₂, CHF₃, C₂F₆, and/or C₃F₆).

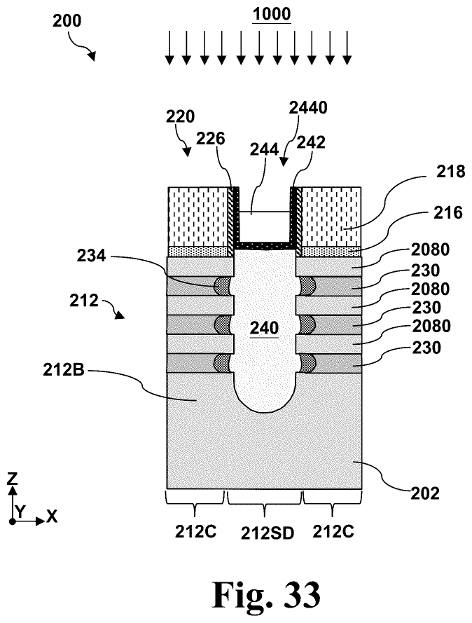

Referring to FIGS. 19 and 33, method 300 includes a block 322 where an ion implantation process 1000 is performed. In some embodiments, the ion implantation process 1000 implants nitrogen (N₂), germanium (Ge), or silicon (Si). In one embodiment, the ion implantation process 1000 implants nitrogen (N₂). In some implementations, the ion implantation process 1000 includes an ion implantation energy between about 0.5 keV and about 2 keV. This implantation energy range is not trivial because it represents the implantation range required for the implantation to reach the CESL 242 without inflicting damages on the source/drain features 240. In terms of dosage, the ion implantation process 1000 may include a dosage between about 5×10¹⁴ cm⁻² and about 2×10¹⁵ cm⁻². Because the ion implantation process 1000 is performed after the ILD layer 244 is recessed and before a capping layer is formed over the top recess 2440, the ion implantation process 1000 can better reach dangling bonds on the gate spacer 226. The ion implantation process 1000 is configured to neutralize the dangling bonds on or around the gate spacer 226 without causing undesirable irreversible damages to neighboring structures.

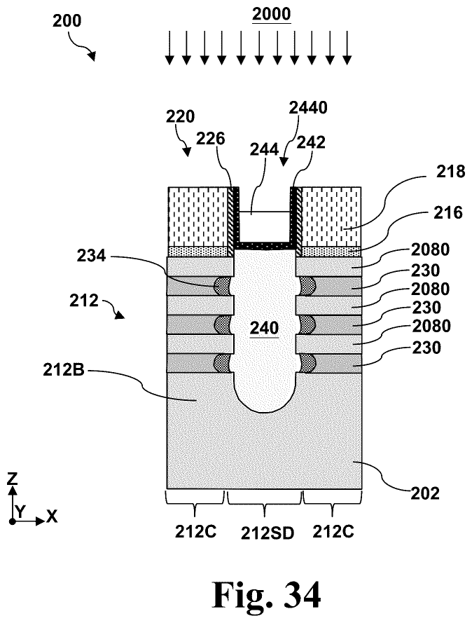

Referring to FIGS. 19 and 34, method 100 includes a block 324 where an anneal process 2000 is performed. While parameters of the ion implantation process 1000 are selected to minimize damages, it inevitably may cause damaged bonds near or around the gate spacer 226. These damaged bonds, if left untreated, may become source of dangling bonds or oxygen atoms. At block 324, the anneal process 2000 is performed to repair and reduce damages or defects caused by the ion implantation process 1000. In some embodiments, the anneal process 2000 may include a micro sub-second anneal (μsash). In some instances, the anneal process 2000 may include an anneal temperature between about 900° C. and about 1300° C. and an anneal time between about 100 milliseconds and about 10 seconds.

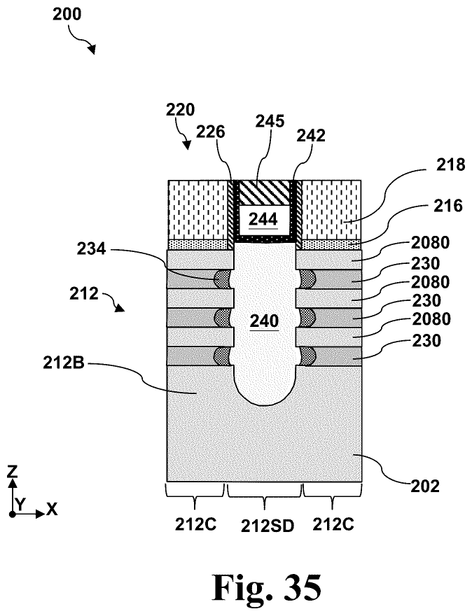

Referring to FIGS. 19 and 35, method 300 includes a block 326 where a capping layer 245 is formed over the top recess 2440. In some embodiments, the capping layer 245 may include a dielectric material that allows selective etching of dummy gate electrode 218, the dummy gate dielectric layer 216, and the sacrificial layers 206. In some embodiments, the capping layer 245 may include silicon nitride. The capping layer 245 functions to protect the ILD layer 244 from being damaged during the removal of the dummy layer 230. A planarization process is performed to remove excess capping layer 245 and to expose the dummy gate stack 220. After the planarization, top surfaces of the capping layer 245, the CESL 242, the gate spacer layer 226, and the dummy gate stacks 220 are coplanar.

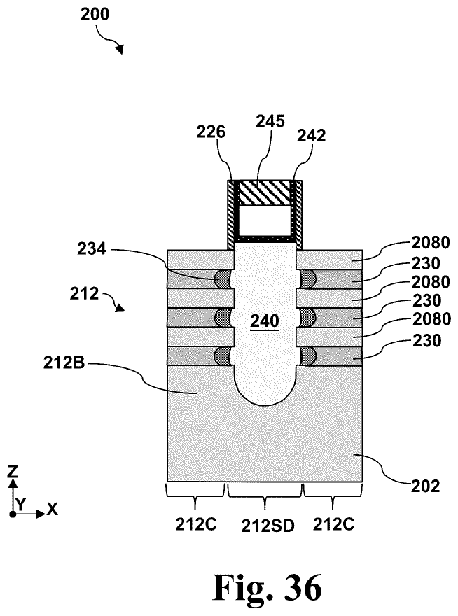

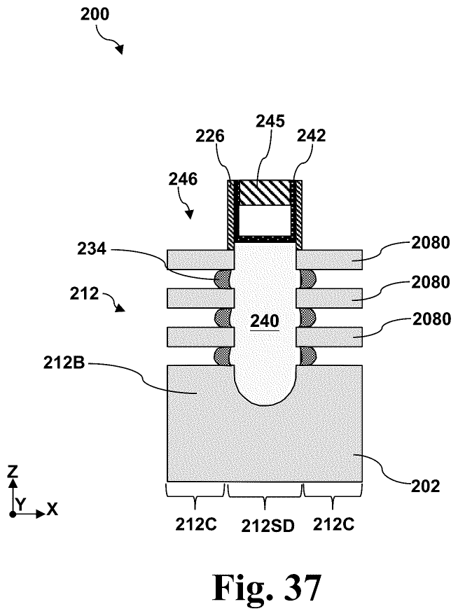

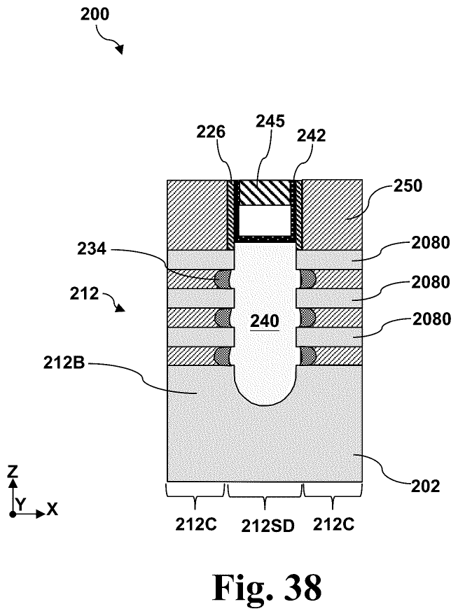

Referring to FIGS. 19 and 36-38, method 300 includes a block 328 where the dummy gate stack 220 and the dummy layer 230 are replaced with a gate structure 250. Operations at block 328 may include removal of the dummy gate stack 220 (shown in FIG. 36), removal of the dummy layer 230 (shown in FIG. 37), and deposition of the gate structure 250 to wrap around each of the channel members 2080 (shown in FIG. 38). At conclusion of the operations at block 326, a planarization process is performed to expose the dummy gate stack 220. Exposure of the dummy gate stack 220 allows the removal thereof. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. As shown in FIG. 36, after the removal of the dummy gate stack 220, the channel members 2080 and the dummy layer 230 in the channel region 212C are exposed.

After the removal of the dummy gate stack 220, a separate etch process may be performed to selectively remove the dummy layer 230 in the channel region 212C. For example, a selective wet etch process or a selective dry etch process may be performed to remove the dummy layer 230. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoro methane (CHF₃), nitrogen trifluoride (NF₃), hydrogen (H₂), ammonia (NH₃), carbon tetrafluoride (CF₄), sulfur hexafluoride (SF₆), or a combination thereof. In one embodiment, a selective wet etch process is used at block 328. After the selective removal of the dummy layer 230, the channel members 2080 in the channel region 212C are once again exposed as shown in FIG. 37.

After the release of the channel members 2080, the gate structure 250 is formed to wrap around each of the channel members 2080 as shown in FIG. 38. While not explicitly shown, the gate structure 250 includes an interfacial layer interfacing the channel members 2080 and the substrate 202 in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 250 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure 250 includes portions that interpose between channel members 2080 in the channel region 212C. In some embodiments, the gate structure 250 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080.

In one exemplary aspect, the present disclosure is directed to a method. The method includes receiving a structure that includes a source/drain feature sandwiched between a first channel region and a second channel region, a first dummy gate stack over the first channel region, a first gate spacer extending along a sidewall of the first dummy gate stack, a second dummy gate stack over the second channel region, a second gate spacer extending along a sidewall of the second dummy gate stack, and an interlayer dielectric (ILD) layer over the source/drain feature and disposed between the first gate spacer and the second gate spacer, selectively recessing the ILD layer to form a top recess, after the selectively recessing, performing an ion implantation process to the structure, and after the performing of the ion implantation process, forming a capping layer in the top recess.

In some embodiments, an ion implantation process implants nitrogen (N₂), germanium (Ge), or silicon (Si). In some embodiments, the method further includes after the performing of the ion implantation process, performing an anneal process. In some embodiments, the anneal process includes a micro second annealing process. In some embodiments, the ion implantation process and the anneal process are configured to result in a tensile stress in the ILD layer. In some embodiments, the ion implantation process includes an implantation energy between about 0.5 keV and about 2 KeV. In some instances, the ion implantation process includes an implantation dosage between about 0.5×10¹⁴ and about 2×10¹⁵. In some implementations, the ion implantation process is configured to remove dangling bond along surfaces of the first gate spacer and the second gate spacer. In some embodiments, the structure further includes a contact etch stop layer (CESL) extending from between the first gate spacer and the ILD layer, to between the ILD layer and the source/drain feature, and then to between the second gate spacer layer and the ILD layer. In some embodiments, the capping layer includes silicon nitride.

In another exemplary aspect, the present disclosure is directed to a method. The method includes receiving a structure that includes a source/drain feature sandwiched between a first channel region and a second channel region, each of the first channel region and the second channel region including a plurality of channel layers interleaved by a plurality of sacrificial layers, a first dummy gate stack over the first channel region, a first gate spacer extending along a sidewall of the first dummy gate stack, a second dummy gate stack over the second channel region, a second gate spacer extending along a sidewall of the second dummy gate stack, and an interlayer dielectric (ILD) layer over the source/drain feature and disposed between the first gate spacer and the second gate spacer, selectively recessing the ILD layer to form a recess, after the selectively recessing, performing an ion implantation process to the structure, performing an anneal process, after the anneal process, forming a capping layer in the recess, removing the first dummy gate stack and the second dummy gate stack, selectively removing the plurality of sacrificial layers in the first channel region and the second channel region, and forming a first gate structure to wrap around each of the plurality of channel layers in the first channel region and a second gate structure to wrap around each of the plurality of channel layers in the second channel region.

In some embodiments, the plurality of sacrificial layers include silicon germanium. In some embodiments, the plurality of sacrificial layers include silicon oxide. In some embodiments, the ion implantation process implants nitrogen (N₂), germanium (Ge), or silicon (Si). In some embodiments, the anneal process includes a micro second annealing process.

In yet another exemplary aspect, the present disclosure is directed to a method. The method includes receiving a structure that includes a source/drain feature sandwiched between a first channel region and a second channel region, a first dummy gate stack over the first channel region, a first gate spacer extending along a sidewall of the first dummy gate stack, a second dummy gate stack over the second channel region, a second gate spacer extending along a sidewall of the second dummy gate stack, a contact etch stop layer (CESL) extending along a sidewall of the first gate spacer, a top surface of the source/drain feature, and along a sidewall of the second gate spacer, and an interlayer dielectric (ILD) layer over the CESL, selectively recessing the ILD layer to form a top recess, after the selectively recessing, performing an ion implantation process to the structure, after the performing of the ion implantation process, performing an anneal process, and after the performing of the anneal process, forming a capping layer in the top recess.

In some embodiments, the ion implantation process implants nitrogen (N₂), germanium (Ge), or silicon (Si). In some embodiments, the anneal process includes a micro second annealing process. In some embodiments, the ion implantation process includes an implantation energy between about 0.5 keV and about 2 KeV. In some embodiments, the ion implantation process includes an implantation dosage between about 5×10¹⁴ and about 2×10¹⁵.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a structure comprising:
a source/drain feature sandwiched between a first channel region and a second channel region,
a first dummy gate stack over the first channel region,
a first gate spacer extending along a sidewall of the first dummy gate stack,
a second dummy gate stack over the second channel region,
a second gate spacer extending along a sidewall of the second dummy gate stack, and
an interlayer dielectric (ILD) layer over the source/drain feature and disposed between the first gate spacer and the second gate spacer;
selectively recessing the ILD layer to form a top recess;
after the selectively recessing, performing an ion implantation process to the structure; and
after the performing of the ion implantation process, forming a capping layer in the top recess.

2. The method of claim 1, where the ion implantation process implants nitrogen (N₂), germanium (Ge), or silicon (Si).

3. The method of claim 1, further comprising:
after the performing of the ion implantation process, performing an anneal process.

4. The method of claim 3, wherein the anneal process comprises a micro second annealing process.

5. The method of claim 3, where the ion implantation process and the anneal process are configured to result in a tensile stress in the ILD layer.

6. The method of claim 1, where the ion implantation process comprises an implantation energy between about 0.5 keV and about 2 KeV.

7. The method of claim 1, where the ion implantation process comprises an implantation dosage between about 0.5×10¹⁴ and about 2×10¹⁵.

8. The method of claim 1, where the ion implantation process is configured to remove dangling bond along surfaces of the first gate spacer and the second gate spacer.

9. The method of claim 1, wherein the structure further comprises:
a contact etch stop layer (CESL) extending from between the first gate spacer and the ILD layer, to between the ILD layer and the source/drain feature, and then to between the second gate spacer layer and the ILD layer.

10. The method of claim 1, wherein the capping layer comprises silicon nitride.

11. A method, comprising:
receiving a structure comprising:
a source/drain feature sandwiched between a first channel region and a second channel region, each of the first channel region and the second channel region comprising a plurality of channel layers interleaved by a plurality of sacrificial layers;
a first dummy gate stack over the first channel region,
a first gate spacer extending along a sidewall of the first dummy gate stack a second dummy gate stack over the second channel region,
a second gate spacer extending along a sidewall of the second dummy gate stack, and
an interlayer dielectric (ILD) layer over the source/drain feature and disposed between the first gate spacer and the second gate spacer;
selectively recessing the ILD layer to form a recess;
after the selectively recessing, performing an ion implantation process to the structure;
performing an anneal process;
after the anneal process, forming a capping layer in the recess;
removing the first dummy gate stack and the second dummy gate stack;
selectively removing the plurality of sacrificial layers in the first channel region and the second channel region; and
forming a first gate structure to wrap around each of the plurality of channel layers in the first channel region and a second gate structure to wrap around each of the plurality of channel layers in the second channel region.

12. The method of claim 11, wherein the plurality of sacrificial layers comprises silicon germanium.

13. The method of claim 11, wherein the plurality of sacrificial layers comprises silicon oxide.

14. The method of claim 11, where the ion implantation process implants nitrogen (N₂), germanium (Ge), or silicon (Si).

15. The method of claim 11, wherein the anneal process comprises a micro second annealing process.

16. A method, comprising:
receiving a structure comprising:
a source/drain feature sandwiched between a first channel region and a second channel region,
a first dummy gate stack over the first channel region,
a first gate spacer extending along a sidewall of the first dummy gate stack,
a second dummy gate stack over the second channel region,
a second gate spacer extending along a sidewall of the second dummy gate stack,
a contact etch stop layer (CESL) extending along a sidewall of the first gate spacer, a top surface of the source/drain feature, and along a sidewall of the second gate spacer, and
an interlayer dielectric (ILD) layer over the CESL;
selectively recessing the ILD layer to form a top recess;
after the selectively recessing, performing an ion implantation process to the structure;
after the performing of the ion implantation process, performing an anneal process; and
after the performing of the anneal process, forming a capping layer in the top recess.

17. The method of claim 16, where the ion implantation process implants nitrogen (N₂), germanium (Ge), or silicon (Si).

18. The method of claim 16, wherein the anneal process comprises a micro second annealing process.

19. The method of claim 16, where the ion implantation process comprises an implantation energy between about 0.5 keV and about 2 KeV.

20. The method of claim 16, where the ion implantation process comprises an implantation dosage between about 5×10¹⁴ and about 2×10¹⁵.
